(19) United States
(12) Patent Application Publication
(10) Pub. No.: US 2026/0334705 A1
(43) Pub. Date: Oct. 29, 2026

(54) REFRIGERATED FOOD AND DRINK MERCHANDISER TANK RECONDITIONING

(71) Applicant: George Morris, Wellington, FL (US)

(72) Inventor: George Morris, Wellington, FL (US)

(21) Appl. No.: 19/657,262

(22) Filed: Apr. 24, 2026

Related U.S. Application Data
(60) Provisional application No. 63/794,002, filed on Apr. 24, 2025.

(51) Int. Cl. A47F 3/04; G06F 30/10

(52) U.S. Cl. CPC A47F 3/0469; G06F 30/10

(57) ABSTRACT

A method for reconditioning a Refrigerated Food and Drink Merchandiser Tank by digitally measuring multiple points on the tank surface to generate a three dimensional electronic template. The template is used to create a digital image and corresponding data file which serves as the basis for constructing a flexible coated vinyl cover sheet. The method includes applying an expandable closed cell foam adhesive for securing the cover to the tank and drain fitting.

### PRIORITY CLAIM

This application is based upon and claims a priority date from U.S. Provisional Patent Application 63/794,002 entitled REFRIGERATED FOOD AND DRINK MERCHANDISER TANK RECONDITIONING filed Apr. 24, 2025 the contents of which are incorporated herein by reference.

### FIELD OF THE INVENTION

This invention is directed to the field of commercial refrigeration and, in particular, to a method for new and reconditioning used Refrigerated Food and Drink Merchandise Tank to address condensate leakage.

### BACKGROUND OF THE INVENTION

A Refrigerated Food and Drink Merchandiser is a type of refrigerated display or unit that stores food and drink commonly used in grocery stores, Restaurants, Convenience Stores, Liquor Establishments, Portable Food Truck/Trailers, to showcase drinks, prepackaged foods, fresh produce, ice or frozen food. The key feature is that it's open at the front, allowing easy customer access with or without doors. Sometimes these units are accessible from the rear as well. It is well known that unrestricted access to food groups is appreciated by the consumer. For instance, the design makes products highly visible, which can attract attention and encourage impulse purchases. Lighting and tiered shelving enhance the presentation of colorful product and/or produce on the shelving. Since customers interact more freely with the open display, items tend to sell faster, promoting fresher inventory and, where produce is sold, reducing spoilage. The merchandiser increases the sale potential for the grocery store and makes it easy to restock and rearrange items.

Modern Refrigerated Food and Drink Merchandise refrigerated displays direct a stream of cold air (“air curtain”) across the front forming an invisible barrier to help keep cold air within the unit, typically a bottom air return recycles the chilled air for energy efficiency. Further, the unit itself is refrigerated from a base or behind shelving using circulated air to maintain a uniform temperature throughout the display. The sides, back, and base are insulated to keep the internal temperature steady. Night curtains are typically employed at night to minimize heat gain from the environment and reduce energy use.

While a refrigeration system is known to create condensate, the equipment is designed to catch the condensate. For purposes of this description, the area designed to catch and direct the condensate to a drainpipe or an area for evaporation will be termed “Tank.”

For such a system to operate properly, the grocery store must be air-conditioned where temperature and humidity are maintained at a maximum of 75-degree F. dry bulb, and 55% humidity. In a self-contained unit, the condensate tank is positioned near or above the refrigerator compressor in which a heating element gives off heat helping to evaporate any condensate. Alternatively, the tank directs the condensate to a drainpipe. The amount of condensate produced depends on the equipment efficiency and design parameters. Once out of design parameters, the tank can overflow or, due to poor maintenance, condensate can leak through the tank. For instance, the drainpipe can be clogged backing up the condensate. In another example the tank can become corroded and develop cracks or holes allowing leakage. The recommended 3 month cleaning of equipment is seldom adhered to. Without warning, the result can be water on the floor around the equipment. FOOD AND DRINK Merchandiser units are especially prone to condensate dripping due to high humidity which limits evaporation, refrigeration coil issues that cause excess water buildup, and tank issues.

Unfortunately, water on the floor of a commercial building can quickly escalate to an injury. Should a customer or employee slip and fall due to water leakage, an injury and lawsuit is likely. This is especially problematic at grocery stores using polished floors for cleanliness. Commercial buildings have a legal duty to maintain safe conditions for invited customers. If a customer is injured, the grocery store could be found negligent. This is a special concern if an employee should have noticed the hazardous condition and did not report it. Especially if there is a history of leakage or similar complaints.

As the Merchandiser equipment ages, the tank may have been through thousands of refrigerated cycles. The tanks are commonly constructed of sheet metal and sometimes cheap plastic which is susceptible to leaking due to poor maintenance or neglect. When the tank is integrated into the base of the unit, failure of base is likely to occur before the unit's refrigerant system fails. Proper care of the tank greatly extends the longevity of the equipment.

While condensate has a neutral pH, mold, food residues, and cleaning chemicals can make the condensate acidic causing rusting of steel. Rust can rapidly deteriorate the structural integrity of the tank, which can lead to cracks for condensate to leak through. Periodic cleaning of equipment is required but may not be routine as it requires removal of all contents on the Merchandiser. Further, when a cleaning is performed, the use of anything other than a mild soap may leave a cleaning chemical residual that could lead to the aforementioned acidic conditions. Steel is highly susceptible to corrosion by acidic conditions such as spoiled condensate, especially if the pH falls below 6 on the pH logarithmic scale.

What is needed in the industry is a method for treating new or used tanks to eliminate water from creating a hazardous walking/working area.

### SUMMARY OF THE INVENTION

The present invention relates to a method for treating and refurbishing Merchandiser equipment. The method enables the creation of a precisely fitted, protective cover constructed of flexible coated vinyl through a series of digital modeling and fabrication steps.

The method begins with digitally measuring the coordinates of multiple points on the surface of an open merchandise tank used to catch condensate. These measurements are stored in memory and used to construct an accurate electronic model of the tank surface. From this model, a two or three-dimensional electronic image is generated and converted into a data file. This data file serves as a custom tailored template for designing and constructing a custom tank cover.

The cover is manufactured from flexible coated vinyl, specifically tailored to the unique dimensions of the measured tank. To ensure a secure and custom form-fitting installation, the installation includes applying an expandable foam/adhesive mixture onto each corner of the tank and the perimeter of the tank surrounding any protrusions. The vinyl cover is then placed over the corroded or new tank and held in place until the adhesive takes a set.

An objective of the invention is to provide a custom fitted cover for a Merchandiser tank to prevent condensate water from penetrating the tank.

Still another objective of the invention is to provide a method that allows for exact dimensional sizing of a Merchandiser tank cover extending the life of the refrigeration equipment by reconditioning of tanks.

An advantage of the method is that it enables rapid refurbishment of the tank without removing the tank from service. Another advantage of the method is it provides a reusable and adaptable workflow for different tank models and brands.

Other objectives and advantages of this invention will become apparent from the following description taken in conjunction with any accompanying drawings wherein are set forth, by way of illustration and example, certain embodiments of this invention.

### BRIEF DESCRIPTION OF THE DRAWINGS

FIG. 1 depicts a flow diagram of the cover manufacturing and installation steps;

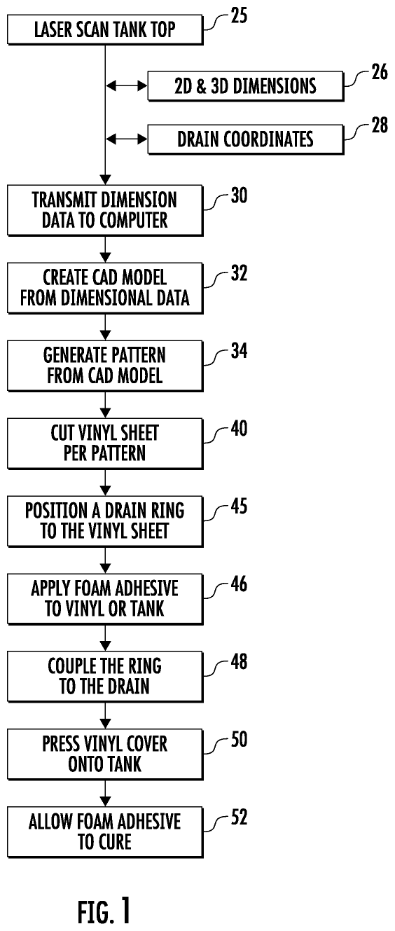

FIG. 2 is a front view of a refrigeration unit in a commercial environment;

FIG. 3 a perspective view of the refrigeration unit with a tank in poor condition;

FIG. 4 is a top view thereof;

FIG. 5 is a top view of the refrigeration unit with a cover installed; and

FIG. 6 is a top view thereof showing a plastic form fitting ring on top of shaped vinyl cover.

### DETAILED DESCRIPTION OF THE INVENTION

A detailed embodiment of the instant invention is disclosed herein; however, it is to be understood that the disclosed embodiment is merely exemplary of the invention, which may be embodied in various forms. Therefore, specific functional and organization of method steps disclosed herein are not to be interpreted as limiting, but merely as a basis for the claims and as a representation basis for teaching one skilled in the art to variously employ the present invention in virtually any appropriately detailed structure.

Referring now to the drawings in general, wherein like reference numerals refer to like elements, illustrated is a refrigerated food and drink merchandiser 10 defined by a base 12 supporting a tank 14 having an upper surface 16. The upper surface 16 of the tank 14 is particularly prone to damage due to water collection typically evident by tank rusting. The merchandiser 10 is further defined by back wall 18 used for support shelving 19 and a top cover 20 housing shelf lighting 22. The upper surface 16 of the tank 14 is measured by a laser scanner 25. The upper surface 16 in need of refurbishing is likely covered with rust that creates an irregular texture that is uneven and can cause scattered reflections or shadowing.

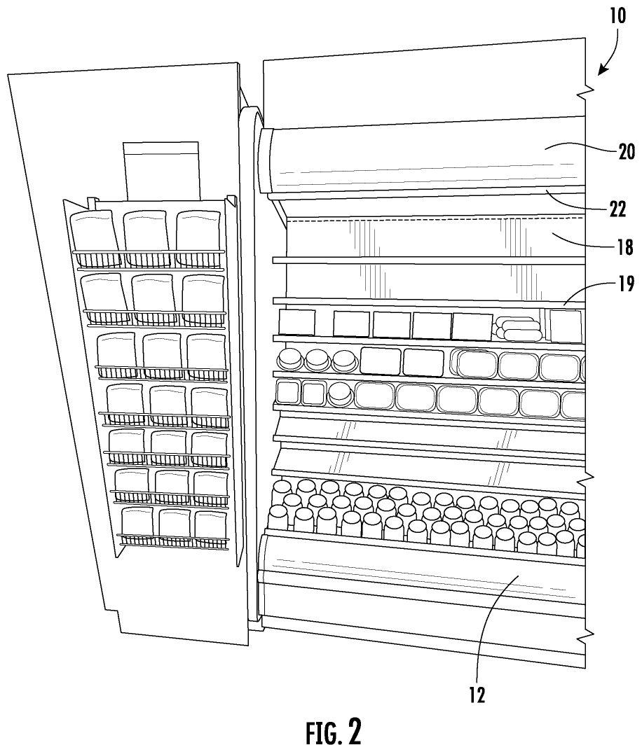

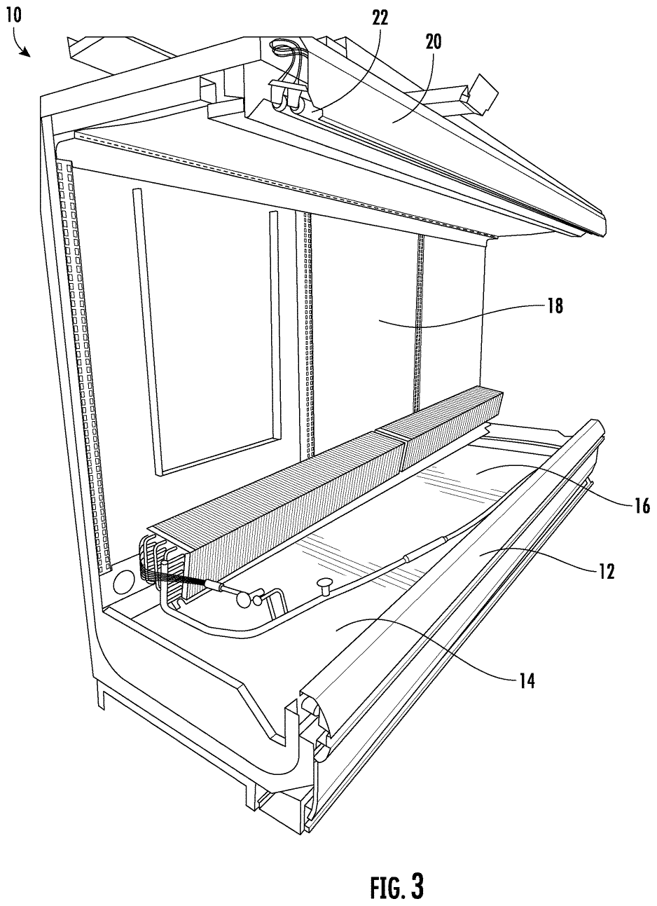

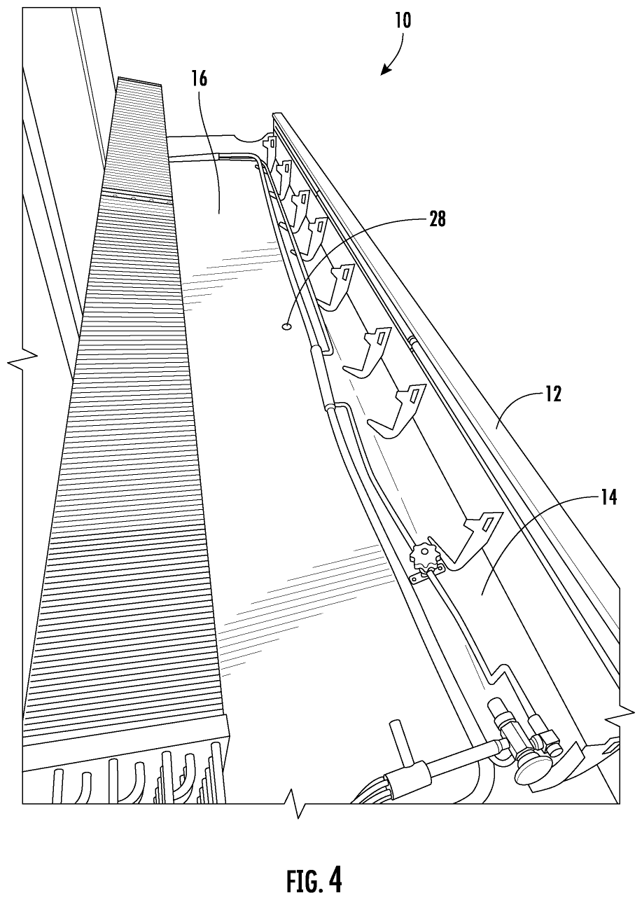

Referring to FIG. 2, the refrigerated food and drink merchandiser 10 is shown in a typical commercial environment, such as a grocery store or restaurant setting, where prolonged exposure to moisture, cleaning agents, and temperature cycling may contribute to deterioration of the tank 14 over time. As illustrated in FIGS. 3 and 4, the tank 14 may exhibit deterioration, including rust, corrosion, pitting, or cracking along the upper surface 16, which may lead to condensate leakage.

The rust is typically dark and matte which can absorb light rather than reflect light. Laser scanners, especially blue or green lasers, can penetrate the surface texture to obtain reliable reflections. For optimal scanning, the tank surface is cleaned just enough to remove loose rust to avoid flaky pieces from interfering with the scan. The scan is performed from several angles to reduce shadowing from pits and grooves, the scanner aligns multiple scans into one full surface map. The laser scanner generates an accurate point cloud or mesh of the corroded surface models showing pitting, bulges, or erosion.

The laser scanning device 25 is employed to scan the upper surface 16 of the tank 14 in order to obtain a plurality of three-dimensional digital coordinates 26 representing the surface geometry of the tank 14 and drain 28. The scan obtains the three-dimensional digital coordinates which are transmitted to a computer memory 30, which stores the data for digital processing and further modeling. A digital model 32 of the merchandiser tank 14 is constructed of the upper surface 16 including any change in shape due to rusting, pitting or cracks using computer-aided design (CAD) software. The three-dimensional digital coordinates providing the digital model 32 includes details such as topographical features, periphery boundaries, and the drain coordinates 28. Based on the digital model 32, a cutting pattern 34 is generated. This pattern 34 corresponds to the top surface 16 and conforms accurately to the topography and dimensional features of the tank upper surface 16. A sheet of flexible, coated vinyl material is selected. Vinyl is a preferred material, although other materials can be used without deviating from the intent of this invention. Vinyl is inherently waterproof and can conform to the shape of the tank, even irregular ones. Vinyl resists mild acids, bases, and some chemicals.

While the preferred embodiment employs laser scanning to obtain the three-dimensional digital coordinates 26, other measurement techniques may be employed, including structured light scanning, photogrammetry, or manual coordinate acquisition methods. Similarly, while a flexible coated vinyl material is described for the cover 42, other conformable, fluid-resistant materials may be utilized, including polymer sheets, elastomeric liners, or composite materials, provided such materials are capable of conforming to the surface geometry of the tank 14 and resisting condensate exposure.

The cutting pattern 40 is used to guide the cutting of the vinyl sheet, thereby forming a shaped vinyl cover 42 that matches the dimensions and contours of the upper surface 16 of the tank 14. This allows cutting of the cover at a job site using a knife blade. Alternatively, the cutting of the vinyl sheet can be performed using a laser, however, fume extraction is required as a laser cut of vinyl releases toxic gas and vapor.

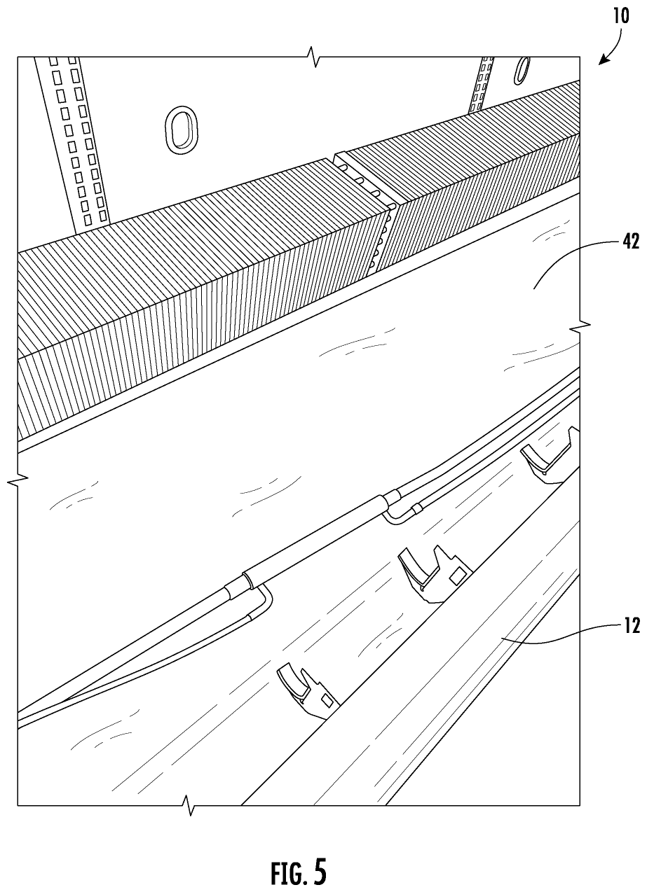

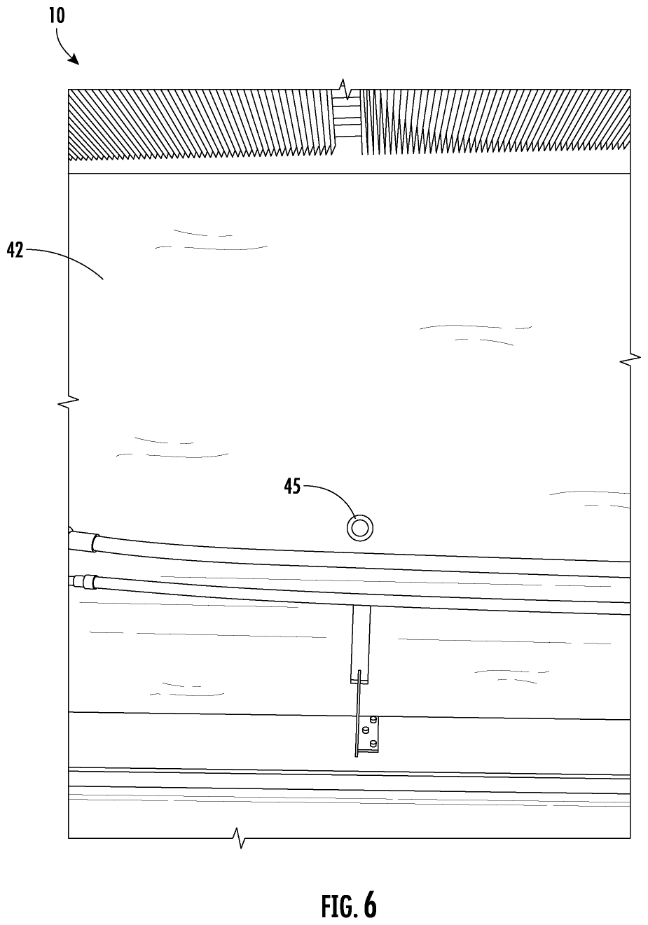

FIGS. 5 and 6 illustrate the merchandiser 10 after installation of the shaped vinyl cover 42, wherein the cover 42 overlays the upper surface 16 of the tank 14. In operation, the installed shaped vinyl cover 42 functions as a barrier layer over the upper surface 16 of the tank 14, inhibiting condensate from contacting and penetrating corroded or compromised regions of the tank 14.

A plastic form-fitting ring 45, as best shown in FIG. 6, is positioned over the shaped vinyl cover 42 and around the drain 28 to secure the cover 42. This ring 45 is designed to align with and seat around the drain 28 of the tank 14, aiding in structural fit and sealing. The positioned form-fitting ring 45 is securely coupled 48 to the drain 28 establishing a physical and/or sealed interface with the existing drain structure.

An admixture of closed-cell foam adhesive 46 is applied either to the inner surface of the shaped vinyl cover 42 or to the upper surface 16 of the merchandiser tank 14, depending on the condition and material compatibility of the tank surface. The conformal fit of the cover 42, in combination with the adhesive 46 and the form-fitting ring 45, reduces pathways for fluid migration and directs condensate toward the drain 28 for proper removal.

The shaped vinyl cover 42 is pressed and held in contact with the corresponding surface 16 of the tank 14. Manual or mechanical pressure 50 is applied until the adhesive begins to set, ensuring a conformal application. The adhesive is allowed to cure 52 under ambient or accelerated conditions. Upon curing, the shaped vinyl cover becomes permanently affixed to the tank 14, resulting in a seamless, protective, and aesthetically enhanced surface.

The term “coupled” is defined as connected, although not necessarily directly, and not necessarily mechanically. The use of the word “a” or “an” when used in conjunction with the term “comprising” in the claims and/or the specification may mean “one,” but it is also consistent with the meaning of “one or more” or “at least one.” The use of the term “or” in the claims is used to mean “and/or” unless explicitly indicated to refer to alternatives only or the alternative are mutually exclusive, although the disclosure supports a definition that refers to only alternatives and “and/or.”

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a method or device that “comprises,” “has,” “includes” or “contains” one or more steps or elements, possesses those one or more steps or elements, but is not limited to possessing only those one or more elements. Likewise, a step of a method or an element of a device that “comprises,” “has,” “includes” or “contains” one or more features, possesses those one or more features, but is not limited to possessing only those one or more features. Furthermore, a device or structure that is configured in a certain way is configured in at least that way, but may also be configured in ways that are not listed.

One skilled in the art will readily appreciate that the present invention is well adapted to carry out the objectives and obtain the ends and advantages mentioned, as well as those inherent therein. The embodiments, methods, procedures and techniques described herein are presently representative of the preferred embodiments, are intended to be exemplary, and are not intended as limitations on the scope. Changes therein and other uses will occur to those skilled in the art which are encompassed within the spirit of the invention and are defined by the scope of the appended claims.

What is claimed is:

1. A method for manufacturing and installing a cover for a merchandiser tank having an upper surface and a drain comprising the steps of:
laser scanning the upper surface of the merchandiser tank to obtain a plurality of three-dimensional digital coordinates representing the surface geometry of the tank including the drain;
transmitting the obtained three-dimensional digital coordinates to a computer memory;
constructing a digital model of the tank using computer-aided design (CAD) software based on the three-dimensional digital coordinates stored in the computer memory;
generating a pattern of at least the upper surface of the tank using the digital model, wherein the pattern conforms to the tank's topography and dimensions;
cutting a sheet of flexible, coated vinyl material in accordance with the generated pattern to form a shaped vinyl cover corresponding to the upper surface of the tank;
positioning a plastic form fitting ring on top of shaped vinyl cover;
applying an admixture of closed cell foam adhesive to either an inner surface of the shaped vinyl cover or a top surface of the tank;
coupling said positioned form fitting ring to a tank drain;
securing the shaped vinyl cover to the tank by pressing and holding the adhesive-coated surface of the vinyl cover in contact with the corresponding tank surface until the adhesive begins to set; and
allowing the adhesive to cure, thereby permanently affixing the shaped vinyl cover to the tank in a conformal fit.

2. The method according to claim 1 further comprising the step of securing said cover in place until said foam adhesive cures.

3. The method according to claim 1, wherein said laser scanning comprises three-dimensional measurement of the upper surface.

4. The method according to claim 1, wherein the laser scanning step includes scanning the upper surface from a plurality of angles and aligning multiple scans to generate a composite surface map.

5. The method according to claim 1, wherein the digital model includes topographical features, periphery boundaries, and coordinates of the drain.

6. The method according to claim 1, wherein the flexible, coated vinyl material is waterproof and chemically resistant.

7. The method according to claim 1, wherein the adhesive is applied to reduce pathways for fluid migration and direct condensate toward the drain.

8. The method according to claim 1, wherein the plastic form-fitting ring establishes a sealed interface with the tank drain.

9. The method according to claim 1, wherein the three-dimensional digital coordinates are obtained using a technique selected from the group consisting of laser scanning, structured light scanning, photogrammetry, and manual coordinate acquisition.

10. An apparatus for covering a merchandiser tank having an upper surface and a drain, comprising:
a shaped cover formed from a flexible, fluid-resistant material and configured to conform to the upper surface of the merchandiser tank;
an adhesive layer disposed between the shaped cover and the upper surface of the merchandiser tank, the adhesive layer comprising a closed-cell foam adhesive configured to bond the shaped cover to the merchandiser tank; and
a form-fitting ring positionable over the shaped cover and around the drain, the form-fitting ring being configured to couple to the drain to secure the shaped cover and establish a sealed interface at the drain.

11. The apparatus according to claim 10, wherein the shaped cover is formed from coated vinyl.

12. The apparatus according to claim 10, wherein the shaped cover is configured based on a digital model of the merchandiser tank generated from three-dimensional scan data.

13. The apparatus according to claim 10, wherein the shaped cover conforms to surface irregularities including rust, pitting, or cracking.

14. The apparatus according to claim 10, wherein the adhesive layer is configured to reduce fluid migration between the shaped cover and the merchandiser tank and to direct condensate toward the drain.

15. The apparatus according to claim 10, wherein the flexible, fluid-resistant material comprises a material selected from the group consisting of coated vinyl, polymer sheets, elastomeric liners, and composite materials.
